(19) United States
(12) Patent Application Publication
(10) Pub. No.: US 2024/0342854 A1
(43) Pub. Date: Oct. 17, 2024

(54) POLISHING APPARATUS AND POLISHING END POINT DETECTION METHOD IN POLISHING APPARATUS

(71) Applicant: EBARA CORPORATION, Tokyo (JP)

(72) Inventors: Hiroki NAKAMURA, Tokyo (JP); Yuta SUZUKI, Tokyo (JP); Yusuke WATANABE, Tokyo (JP); Michiaki MATSUDA, Tokyo (JP); Koki YAMAMOTO, Tokyo (JP); Taro TAKAHASHI, Tokyo (JP)

(21) Appl. No.: 18/294,730

(22) PCT Filed: Jul. 4, 2022
(86) PCT No.: PCT/JP2022/026550

§ 371 Date: Feb. 2, 2024

(30) Foreign Application Priority Data
Aug. 6, 2021 (JP) 2021-130002

(51) Int. Cl. B24B 37/013; B24B 49/00; B24B 49/04

(52) U.S. Cl. CPC B24B 37/013; B24B 49/003; B24B 49/045

(57) ABSTRACT

To accurately detect a polishing end point even if a change in a polishing frictional force is small. A polishing apparatus includes a polishing table for holding a polishing pad, a holder for holding a polishing target object such that the polishing target object faces the polishing pad, and an end point detector that detects, based on a signal indicating a state of polishing of the polishing target object by the polishing pad, a polishing end point indicating an end of the polishing. The end point detector is configured to remove noise of the signal, exponentiate the signal subjected to the noise removal with an exponent greater than 1, and detect the polishing end point based on the exponentiated signal.

### TECHNICAL FIELD

The present invention relates to a polishing apparatus and a polishing end point detection method in the polishing apparatus.

### BACKGROUND ART

As one of semiconductor device manufacturing apparatuses, there is a CMP (Chemical Mechanical Polishing) apparatus. A representative CMP apparatus includes a polishing table to which a polishing pad is attached and a polishing head to which a substrate, which is a polishing target, is attached. In the representative CMP apparatus, the substrate is polished by supplying polishing liquid to the polishing pad and rotating at least one of the polishing table and the polishing head in a state in which the polishing pad and the substrate are set in contact.

In a polishing process in a polishing apparatus such as a CMP apparatus, it is important to accurately detect a polishing end point where a film that should be removed is removed by polishing. As a method of detecting the polishing end point, there is known a method of detecting a change in a polishing frictional force at the time when a material of the surface of a polishing target object has been shifted to a substance of a different material by polishing (see, for example, PTL 1).

### CITATION LIST

### Patent Literature

PTL 1: Japanese Patent Laid-Open No. 2019-098475

### SUMMARY OF INVENTION

### Technical Problem

When the change in the polishing frictional force at the time when the material of the surface of the polishing target has been shifted to the substance of the different material by the polishing is small, misdetection of the polishing end point is likely to be caused by the influence of noise. Therefore, it is requested to accurately detect the polishing end point even if the change in the polishing frictional force is small.

### Solution to Problem

[Aspect 1] According to an aspect 1, there is provided a polishing apparatus including: a polishing table for holding a polishing pad; a holder for holding a polishing target object such that the polishing target object faces the polishing pad; and an end point detector that detects, based on a signal indicating a state of polishing of the polishing target object by the polishing pad, a polishing end point indicating an end of the polishing, wherein the end point detector is configured to remove noise of the signal, exponentiate the signal subjected to the noise removal with an exponent greater than 1, and detect the polishing end point based on the exponentiated signal.

[Aspect 2] According to an aspect 2, there is provided the polishing apparatus according to the aspect 1, wherein the end point detector is configured to, in order to remove the noise of the signal, moving-average the signal, differentiate a signal obtained by the moving averaging, and further moving-average a signal obtained by the differentiation.

[Aspect 3] According to an aspect 3, there is provided the polishing apparatus according to the aspect 1 or 2, wherein the end point detector is configured to, in the exponentiation of the signal subjected to the noise removal, exponentiate an absolute value of the signal subjected to the noise removal with the exponent greater than 1.

[Aspect 4] According to an aspect 4, there is provided the polishing apparatus according to any one of the aspects 1 to 3, further including a motor for driving to rotate the polishing table, wherein the signal is a signal based on a driving current of the motor.

[Aspect 5] According to an aspect 5, there is provided the polishing apparatus according to any one of the aspects 1 to 3, further including a motor for rotating the polishing target object, wherein the signal is a signal based on a driving current of the motor.

[Aspect 6] According to an aspect 6, there is provided the polishing apparatus according to any one of the aspects 1 to 3, further including an acoustic or ultrasonic sensor disposed near the polishing table or the polishing target object, wherein the signal is a signal sensed by the acoustic or ultrasonic sensor.

[Aspect 7] According to an aspect 7, there is provided a method of detecting a polishing end point indicating an end of polishing in a polishing apparatus, the polishing apparatus including: a polishing table for holding a polishing pad; and a holder for holding a polishing target object such that the polishing target object faces the polishing pad, the method including: a step of acquiring a signal indicating a state of polishing of the polishing target object by the polishing pad; a step of removing noise of the signal; a step of exponentiating the signal subjected to the noise removal with an exponent greater than 1; and a step of detecting the polishing end point based on the exponentiated signal.

### BRIEF DESCRIPTION OF DRAWINGS

FIG. 1 is a schematic diagram illustrating an overall configuration of a polishing apparatus according to an embodiment of the present invention.

FIG. 2 is a schematic diagram illustrating the overall configuration of the polishing apparatus according to the embodiment of the present invention.

FIG. 3 is a flowchart illustrating a series of processing performed by an end point detector according to the embodiment of the present invention.

FIG. 4 illustrates an exemplary polishing signal acquired from a current detector.

FIG. 5 illustrates an exemplary signal obtained by moving-averaging the polishing signal illustrated in FIG. 4.

FIG. 6 illustrates an exemplary signal obtained by differentiating and further moving-averaging the signal illustrated in FIG. 5.

FIG. 7 illustrates an exemplary signal obtained by exponentiating the signal subjected to the noise removal illustrated in FIG. 6.

### DESCRIPTION OF EMBODIMENTS

An embodiment of the present invention is explained below with reference to the drawings. In the drawings referred to below, the same or equivalent components are denoted by the same reference numerals and signs, and redundant explanation of the components is omitted.

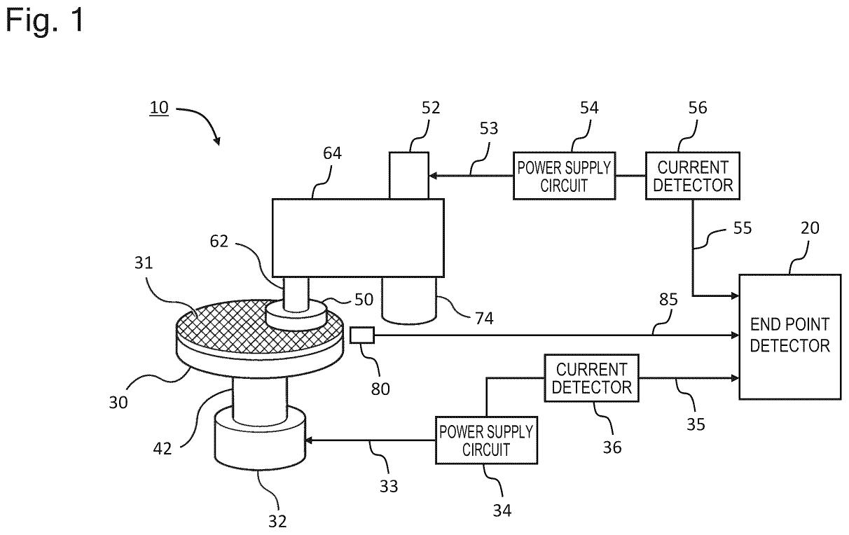

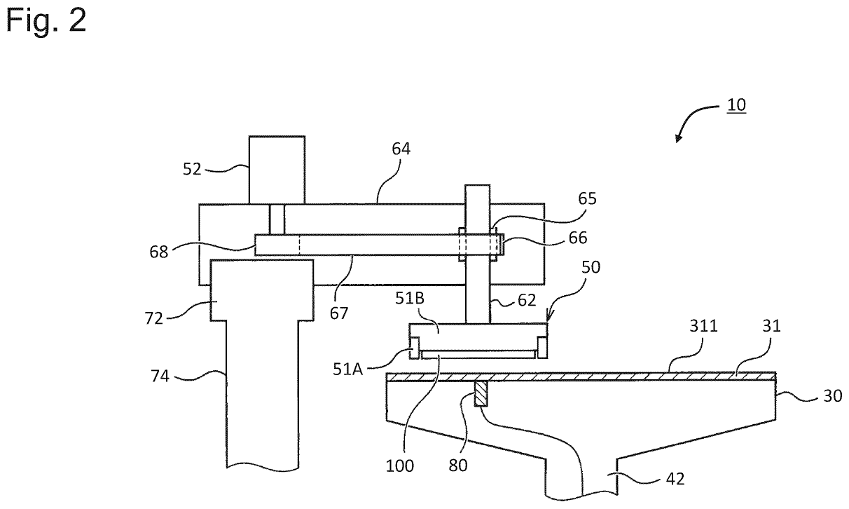

FIG. 1 and FIG. 2 are schematic diagrams illustrating an overall configuration of a polishing apparatus 10 according to an embodiment of the present invention. As illustrated, the polishing apparatus 10 includes a polishing table 30 for holding a polishing pad 31, a top ring 50 (a holder) that holds a polishing target object (for example, a substrate 100 such as a semiconductor wafer illustrated in FIG. 2) to face the polishing pad 31 and presses the polishing target object against a polishing surface of the polishing pad 31, a table drive motor 32 for rotating the polishing table 30, a top ring drive motor 52 for rotating the top ring 50, a power supply circuit 34 that supplies driving power 33 to the table drive motor 32, and a power supply circuit 54 that supplies driving power 53 to the top ring drive motor 52. Note that the table drive motor 32 and the power supply circuits 34 and 54 are omitted in FIG. 2.

The polishing table 30 is coupled to, via a table shaft 42, the table drive motor 32 disposed below the polishing table 30. The table drive motor 32 drives rotation, whereby the polishing table 30 is capable of rotating around the axis of the table shaft 42. The polishing pad 31 is stuck to the upper surface of the polishing table 30. A surface 311 of the polishing pad 31 configures a polishing surface for polishing the substrate 100. A not-illustrated polishing liquid supply nozzle is installed above the polishing table 30. Polishing liquid is supplied to the polishing pad 31 on the polishing table 30 from the polishing liquid supply nozzle.

The top ring 50 is supported by an arm 64 via a top ring shaft 62. The top ring shaft 62 is movable up and down with respect to the arm 64 by a not-illustrated up-down movement mechanism. The top ring 50 can be lifted and lowered and positioned with respect to the arm 64 according to the up-down movement of the top ring shaft 62. The top ring 50 is configured to be able to hold the substrate 100 such as a semiconductor wafer on the lower surface of the top ring 50. Specifically, the top ring 50 includes, as illustrated in FIG. 2, a retainer ring 51A that holds the outer circumferential edge of the substrate 100 to prevent the substrate 100 from protruding from the top ring 50 and a top ring main body 51B that presses the substrate 100 against the polishing surface 311.

The top ring drive motor 52 is fixed to the arm 64 that supports the top ring 50. As illustrated in FIG. 2, the top ring shaft 62 is coupled to a rotary cylinder 65. A timing pulley 66 provided in the outer circumference of the rotary cylinder 65 is connected to, via a timing belt 67, a timing pulley 68 provided in the top ring drive motor 52. Consequently, when the top ring drive motor 52 rotates, the rotary cylinder 65 and the top ring shaft 62 integrally rotate via the timing pulley 68, the timing belt 67, and the timing pulley 66, and the top ring 50 rotates around the axis of the top ring shaft 62.

The arm 64 is coupled to an arm drive motor 72 fixed to an arm shaft 74. According to driving of the arm drive motor 72, the arm 64 and the top ring 50 supported by the arm 64 are capable of turning around the axis of the arm shaft 74.

When the polishing apparatus 10 performs an operation, first, the top ring 50 receives, in a predetermined receiving position, the substrate 100 conveyed by a not-illustrated conveying mechanism (a transporter) and holds the substrate 100. The top ring 50, which has received the substrate 100 in the receiving position, is moved in the upward direction of the polishing table 30 from the receiving position by the turning of the arm 64. Subsequently, the top ring shaft 62 and the top ring 50 are lowered, and the substrate 100 is pressed against the polishing surface 311 of the polishing pad 31. Then, the table drive motor 32 and the top ring drive motor 52 drive rotation, whereby the polishing table 30 and the top ring 50 respectively rotate. At the same time, the polishing liquid is supplied onto the polishing pad 31 from the polishing liquid supply nozzle provided above the polishing table 30. Consequently, the substrate 100 comes into slide contact with the polishing surface 311 of the polishing pad 31 and the surface of the substrate 100 is polished.

Note that, while the substrate 100 is polished, the arm drive motor 72 may periodically turn the arm 64 to the left and the right to perform the polishing while swinging the top ring 50 with respect to the polishing pad 31 (that is, reciprocating the top ring 50 in a predetermined range on the polishing pad 31).

The polishing apparatus 10 in this embodiment further includes a current detector 36 configured to detect a driving current 33 supplied from the power supply circuit 34 to the table drive motor 32, a current detector 56 configured to detect a driving current 53 supplied from the power supply circuit 54 to the top ring drive motor 52, and an end point detector 20 configured to detect, based on the driving currents 33 and 53 or another signal indicating a state of polishing, a polishing end point indicating an end of the polishing. One of the current detectors 36 and 56 may be omitted.

Here, the substrate 100 (for example, a semiconductor wafer), which is a polishing target object, has a laminated structure made of a plurality of different materials such as a semiconductor, a conductor, and an insulator. Coefficients of friction are different among different material layers. Therefore, polishing shifts from a certain layer to another different material layer of the laminated structure, whereby a change occurs in a polishing frictional force in polishing a polishing target object. The polishing frictional force appears as driving loads of the motors 32 and 52 that drive to rotate the polishing table 30 or the top ring 50. Therefore, the electric currents 33 and 53 flowing to the motors 32 and 52 change according to the polishing frictional force, that is, a material of a surface to be polished for which the polishing is performed. An end point of the polishing can be detected using this fact. The detection of the polishing end point can be performed based on only one of the driving currents 33 and 53 or can be performed based on both of the driving currents 33 and 53.

The end point detector 20 may be configured as, for example, a computer including a processor and a memory. A program (software) including one or a plurality of computer-executable instructions is stored in the memory. Processing for detecting the polishing end point may be performed by the processor reading the program from the memory and executing the program. For example, the end point detector 20 can operate to acquire electric signals or data (35, 55) corresponding to the driving currents (33, 53) from the current detectors (36, 56), perform an arithmetic operation (data processing) of the electric signals or the data (35, 55) to identify a change in a polishing frictional force, and detect the polishing end point based on an identification result.

As explained above, the driving currents 33 and 53 of the motors represent a state (a frictional force) of the polishing for the polishing target object. However, it is also possible to detect the end point of the polishing using signals other than the driving currents 33 and 53. In such an embodiment, the polishing apparatus 10 may include a sensor 80 that detects a physical quantity reflecting the state of the polishing. The end point detector 20 may detect the polishing end point based on an output signal 85 of the sensor 80. For example, the sensor 80 may be an acoustic sensor or an ultrasonic sensor installed near the polishing table 30 or the top ring 50 in order to detect polishing sound. As explained above, the change occurs in the polishing frictional force when the material of the surface to be polished changes according to the progress of the polishing. At this time, a change also occurs in the polishing sound. Accordingly, the polishing end point can also be detected by using an output signal from the acoustic sensor or the ultrasonic sensor. As another example, the sensor 80 may be a force sensor that directly detects a polishing frictional force between the polishing table 30 and the top ring 50 as rotational torque of the polishing table 30 or rotational torque of the top ring 50. Alternatively, an eddy current sensor may be used as a vibration detection sensor. Note that, in FIG. 2, the sensor 80 is drawn as being embedded in the polishing table 30. However, a disposition position of the sensor 80 is not limited to this. The sensor 80 only has to be installed in an appropriate position corresponding to a type of the sensor 80.

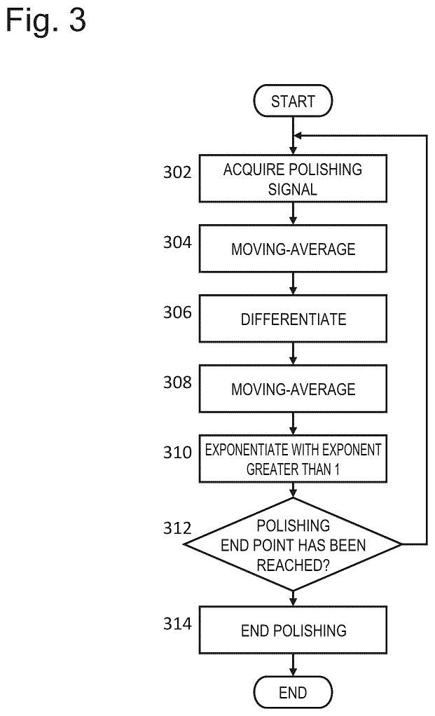

FIG. 3 is a flowchart illustrating a series of processing performed by the end point detector 20. First, the end point detector 20 acquires a signal (hereinafter referred to as polishing signal) S1 representing a state of polishing for a polishing target object (step 302). For example, the polishing signal S1 may be one or a plurality of signals among of i) a signal 35 that can be acquired from the current detector 36, ii) a signal 55 that can be acquired from the current detector 56, and iii) a signal 85 that can be acquired from the sensor 80. As explained above, the signal 35 from the current detector 36 is the signal representing the driving current 33 of the table drive motor 32 and the signal 55 from the current detector 56 is the signal representing the driving current 53 of the top ring drive motor 52. These signals 35 and 55 reflect the driving loads of the motors 32 and 52, that is, the frictional force of the polishing for the polishing target object. The signal 85 from the sensor 80 is, for example, a signal representing polishing sound. The signal 85 also reflects the polishing frictional force.

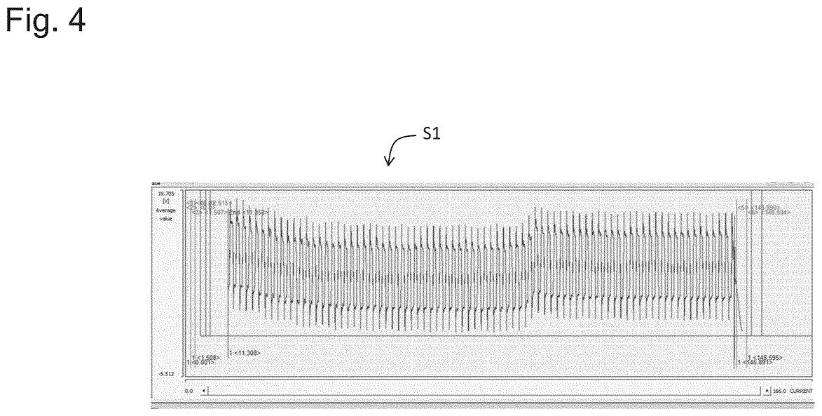

As an example, FIG. 4 illustrates an exemplary polishing signal S1 (that is, the signal 55) acquired from the current detector 56. The horizontal axis of FIG. 4 indicates time and the vertical axis of FIG. 4 indicates signal intensity. This signal represents the driving current 53 of the top ring drive motor 52. Note that this example is an example of performing polishing while swinging the top ring 50 with respect to the polishing pad 31. Fluctuation of the signal at a short time period in a graph is due to the swinging of the top ring 50. That is, the polishing signal S1 in this example includes, besides noise, the fluctuation at the short time period due to the swinging of the top ring 50.

Subsequently, the end point detector 20 performs noise removal on the polishing signal S1. Noise removal processing may include a plurality of processing steps. For example, the end point detector 20 may operate to execute, in order, a step of moving-averaging the polishing signal S1 to generate a signal S2 (step 304), a step of differentiating the signal S2 to generate a signal S3 (step 306), and a step of moving-averaging the signal S3 to generate a signal S4 (step 308).

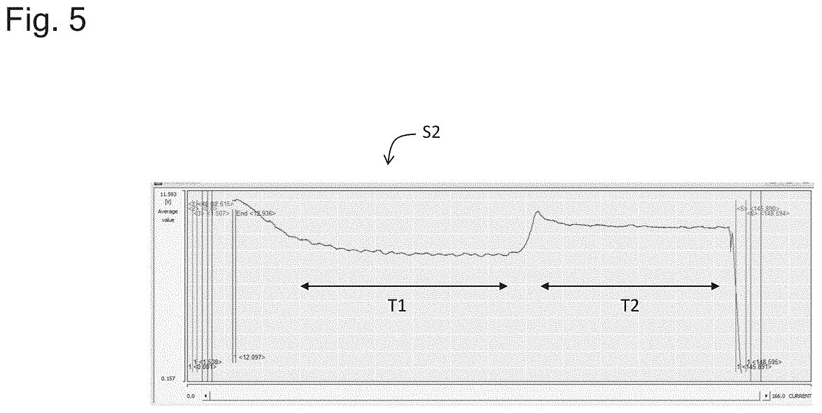

FIG. 5 illustrates an exemplary signal S2 (that is, a signal after step 304) obtained by the end point detector 20 moving-averaging the polishing signal S1 illustrated in FIG. 4. In FIG. 5, periodical fluctuation of a signal due to swinging is removed and noise mixed in the signal is removed to a certain degree by moving average processing. Note that the width of a period in which the moving averaging is performed (that is, the number of data to be averaged) only has to be set as appropriate considering a period of the swinging, a characteristic of assumed noise, and the like. It is seen that, in the moving-averaged signal S2 illustrated in FIG. 5, a time domain T2 in which a value of a signal is relatively large follows a time domain T1 in which a value of a signal is relatively small. As explained above, this is due to the change in the polishing frictional force for the polishing target object. That is, the surface to be polished of the polishing target object transitions from a certain material to another material between the former time domain T1 and the latter time domain T2. An instance of this transition corresponds to the end point of the polishing.

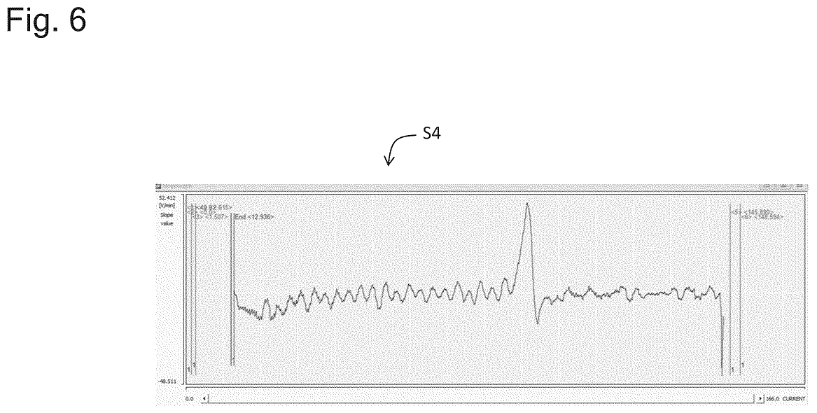

FIG. 6 illustrates an exemplary signal S4 (that is, a signal after step 308) obtained by the end point detector 20 differentiating and further moving-averaging the signal S2 illustrated in FIG. 5. In FIG. 6, a signal having a steep peak is obtained by differential processing. As it is understood from the above explanation, this signal peak corresponds to the polishing end point. In FIG. 6, noise of a signal is removed to a certain degree by moving average processing after the differentiation. However, noise cannot be entirely removed and remains in a skirt portion other than the steep peak. Depending on the magnitude of this remaining noise, it is difficult to accurately discriminate the peak portion of the signal and the noise. Therefore, it is requested to more effectively reduce the noise to thereby more accurately detect the polishing end point.

Note that the noise removal processing is not limited to the noise removal processing illustrated in steps 304 to 308. The end point detector 20 may perform the noise removal from the polishing signal S1 using another method.

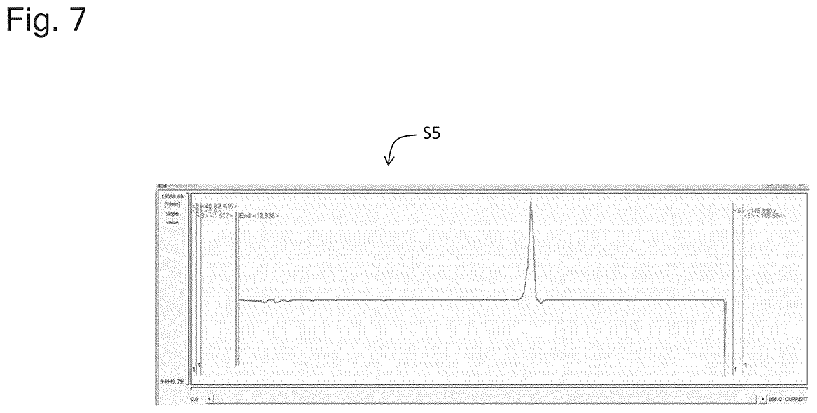

Referring back to FIG. 3, subsequently, the end point detector 20 exponentiates the signal (for example, the signal S4) subjected to the noise removal as explained above with an exponent greater than 1 (step 310). The exponent of the exponentiation may be, for example, 2 or 3 (that is, second power or third power). FIG. 7 illustrates an exemplary signal S5 obtained by raising the signal S4 subjected to the noise removal illustrated in FIG. 6 to the third power. In FIG. 7, a value of the signal is increased to be larger by the exponentiation (the third power) at a peak where the value of the signal is large and in a portion near the peak. On the other hand, the value of the signal is reduced to be smaller by the exponentiation (the third power) in a skirt portion where the value of the signal is small, that is, a portion mainly including noise compared with the peak and the portion near the peak. That is, an increase in the value of the signal by the exponentiation at the peak and in the portion near the peak is far greater than an increase in the value of the signal by the exponentiation in the portion mainly including noise. As a result, noise further decreases in the signal S5 after the exponentiation processing compared with the signal S4. The signal S5 has a waveform in which a peak portion is more conspicuous. By using such a signal S5, it is possible to accurately detect the polishing end point.

Note that the absolute value of the signal may be calculated before the exponentiation is calculated in step 310. That is, the end point detector 20 may calculate, according to plus or minus of a value X of a signal (for example, the signal S4), exponentiation Y of the value X as follows.

$$When$$

$$X \geq 0 ,$$

$$Y = {\{ abs ( X ) \}}^{N}$$

$$When$$

$$X < 0 ,$$

$$Y = - {\{ abs ( X ) \}}^{N}$$

Consequently, even when an even number or a decimal value is used as an exponent N, it is possible to avoid plus and minus of the exponential Y being inverted with respect to a minus number X and a value of the exponentiation Y becoming an imaginary number and calculate an exponentiated appropriate signal (for example, the signal S5) in step 310.

Subsequently, the end point detector 20 determines, based on the exponentiated signal (for example, the signal S5), whether the polishing end point has been reached (step 312). For example, referring to FIG. 7, the end point detector 20 may determine whether a value of the signal S5 has exceeded a predetermined threshold. Note that, depending on the coefficients of friction of the materials of the layers configuring the polishing target object, it could occur that a magnitude relation between a signal value of a former half time T1 and a signal value of a latter half time T2 in the signal S2 illustrated in FIG. 5 is opposite to the example illustrated in FIG. 5 (that is, the signal value in the time T2 is smaller than the signal value in the time T1). In such a case, the signal S5 illustrated in FIG. 7 has a peak convex downward. The end point detector 20 only has to determine whether the value of the signal S5 has fallen below the predetermined threshold.

When the polishing end point has been reached in the determination in step 312, the end point detector 20 determines to end the polishing of the polishing target object being polished (step 314). In response to the determination of the polishing end, the polishing table 30 and the top ring 50 stop rotating, the top ring 50 is lifted from the polishing table 30, and the substrate 100 is detached from the top ring 50 and passed to the next process (for example, a cleaning process). On the other hand, if the polishing end point has not been reached yet, the end point detector 20 returns to step 302 in order to continue the detection of the polishing end point and repeats step 302 and subsequent steps using a signal at a newer time point.

Note that, in the above explanation, the signal waveforms illustrated in FIG. 4 to FIG. 7 are explained using the signal 55 from the current detector 56 as an example of the polishing signal S1. However, in the cases of other signals (for example, the signal 35 from the current detector 36 or the signal 85 from the sensor 80) as well, it is possible to apply steps 302 to 314 in the same manner and detect the polishing end point. The polishing signal S1 illustrated in FIG. 4 is the signal in the case in which the polishing is performed while the top ring 50 being swung. However, the swinging of the top ring 50 may not be performed.

As explained above, according to this embodiment, by subjecting the polishing signal to the noise removal and further exponentiating the polishing signal with the exponent greater than 1, it is possible to make a non-noise portion of the signal conspicuous from a noise portion to thereby accurately detect the polishing end point. Since a noise component of the signal is reduced by the exponentiation, it is also possible to reduce a movement section (reduce the number of data) in the moving average processing in the noise removal processing. That is, even if the movement section is reduced, it is possible to reduce noise of the signal through the exponentiation. Consequently, it is possible to quickly detect the polishing end point. It is possible to prevent excessive polishing of the polishing target object.

The embodiment of the present invention is explained above based on the several examples. However, the embodiment of the invention explained above facilitates understanding of the present invention and does not limit the present invention. It goes without saying that the present invention can be changed and improved without departing from the gist of the present invention and equivalents of the present invention are included in the present invention. Any combination or omission of the constituent elements described in the claims and the description is possible in a range in which at least a part of the problems described above can be solved or a range in which a part of the effects described above can be achieved.

### REFERENCE SIGNS LIST

10 Polishing apparatus
20 End point detector
30 Polishing table
31 Polishing pad
32 Table drive motor
34 Power supply circuit
36 Current detector
42 Table shaft
50 Top ring
51A Retainer ring
51B Top ring main body
52 Top ring drive motor
54 Power supply circuit
56 Current detector
62 Top ring shaft
64 Arm
65 Rotary cylinder
66 Timing pulley
67 Timing belt
68 Timing pulley
72 Arm drive motor
74 Arm shaft
80 Sensor
100 Substrate

1. A polishing apparatus comprising:
a polishing table for holding a polishing pad;
a holder for holding a polishing target object such that the polishing target object faces the polishing pad; and
an end point detector that detects, based on a signal indicating a state of polishing of the polishing target object by the polishing pad, a polishing end point indicating an end of the polishing, wherein
the end point detector is configured to:
remove noise of the signal;
exponentiate the signal subjected to the noise removal with an exponent greater than 1; and
detect the polishing end point based on the exponentiated signal.

2. The polishing apparatus according to claim 1, wherein the end point detector is configured to, in order to remove the noise of the signal:
moving-average the signal;
differentiate a signal obtained by the moving averaging; and
further moving-average a signal obtained by the differentiation.

3. The polishing apparatus according to claim 1, wherein the end point detector is configured to, in the exponentiation of the signal subjected to the noise removal, exponentiate an absolute value of the signal subjected to the noise removal with the exponent greater than 1.

4. The polishing apparatus according to claim 1, further comprising a motor for driving to rotate the polishing table, wherein the signal is a signal based on a driving current of the motor.

5. The polishing apparatus according to claim 1, further comprising a motor for rotating the polishing target object, wherein the signal is a signal based on a driving current of the motor.

6. The polishing apparatus according to claim 1, further comprising an acoustic or ultrasonic sensor disposed near the polishing table or the polishing target object, wherein
the signal is a signal sensed by the acoustic or ultrasonic sensor.

7. A method of detecting a polishing end point indicating an end of polishing in a polishing apparatus,
the polishing apparatus including:
a polishing table for holding a polishing pad; and
a holder for holding a polishing target object such that the polishing target object faces the polishing pad,
the method comprising:
a step of acquiring a signal indicating a state of polishing of the polishing target object by the polishing pad;
a step of removing noise of the signal;
a step of exponentiating the signal subjected to the noise removal with an exponent greater than 1; and
a step of detecting the polishing end point based on the exponentiated signal.
